(19) United States
(12) Patent Application Publication
(10) Pub. No.: US 2026/0061881 A1
(43) Pub. Date: Mar. 5, 2026

(54) METHOD AND APPARATUS FOR RECOMMENDING CHARGING STATION

(71) Applicant: HYUNDAI AUTOEVER CORP., Seoul (KR)

(72) Inventors: Lam LEE, Seoul (KR); Hyung Gab CHO, Seoul (KR); Wang Gon YOO, Seoul (KR)

(21) Appl. No.: 19/307,604

(22) Filed: Aug. 22, 2025

(30) Foreign Application Priority Data
Aug. 29, 2024 (KR) 10-2024-0116426

(51) Int. Cl. B60L 53/66; B60L 53/10; G01R 31/382

(52) U.S. Cl. CPC B60L 53/665; B60L 53/11; G01R 31/382; B60L 2240/62; B60L 2240/72

(57) ABSTRACT

Methods and devices for recommending a charging station are described. In one embodiment, the method comprises identifying a type of business related to a destination of a vehicle, determining a charging type based on the type of business, identifying one or more charging stations including a charger of the charging type among a plurality of charging stations located within a predetermined distance from the destination of the vehicle, and providing a user with the one or more charging stations as recommended charging stations.

### CROSS-REFERENCE TO RELATED APPLICATION

This application claims priority from Korean Patent Application No. 10-2024-0116426 filed on Aug. 29, 2024, in the Korean Intellectual Property Office and all the benefits accruing therefrom under 35 U.S.C. 119, the contents of which in its entirety are herein incorporated by reference.

### BACKGROUND

### Technical Field

The present disclosure relates to a method and apparatus for recommending a charging station, and more particularly, to a method for providing a route to a charging station, which is suitable for a destination and is likely to perform charging in a manner preferred by a user, to improve the user's driving satisfaction, and an apparatus for performing the method.

### Description of the Related Art

A navigation service selects a charging station in accordance with an optimal charging station recommendation logic and provides the selected charging station to a vehicle, when it is determined that the vehicle will not be able to reach a destination with only a current charging amount after a charging amount expected to be required for the vehicle to reach the destination is compared with a remaining battery amount of the vehicle. The navigation service for recommending a charging station aims to relieve driving anxiety of a mobility device driver by allowing the driver to easily deal with an unexpected situation such as lack of a charging amount while driving toward the destination.

The existing optimal charging station recommendation logic selects a charging station by utilizing static/dynamic data such as real-time charging availability, charging station location information, information as to whether the charging station is open, and information on operating hours of the charging station, and provides the selected charging station to a vehicle driver.

However, the existing charging station recommendation logic has a limitation in that a recommended charging station is selected based on logic that only reflects the charging amount and distance without reflecting a charging situation upon arrival at the destination, a user's preference and a charging pattern.

Accordingly, it is required to provide logic that guides a charging station selected by reflecting a charging situation that a user may perform upon arrival at the destination, the user's charging preference, and the user's existing charging pattern.

### PRIOR ART REFERENCE

### Patent Reference

(Patent Reference 1) Laid-Open Patent No. 10-2023-0101347 (published on Jul. 6, 2023)
(Patent Reference 2) Registered Patent No. 10-2304745 (published on Jan. 19, 2021)

### SUMMARY

An object of the present disclosure is to provide a method and apparatus for recommending a charging station based on a type of business of a destination.

Another object of the present disclosure is to provide a method and apparatus for recommending a charging station based on a charging pattern of a user.

Other object of the present disclosure is to provide a method and apparatus for recommending a charging station based on a driving distance to a destination.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a method for recommending a charging station, which is performed by a computing system. The method may comprise: identifying a type of business related to a destination of a vehicle; determining a charging type based on the identified type of business; identifying one or more charging stations including a charger of the determined charging type among a plurality of charging stations located within a predetermined distance from the destination of the vehicle; and providing a user with the identified one or more charging stations as recommended charging stations.

In some embodiments, the determining a charging type may include determining the charging type as a quick charging type in response to determining that the type of business is a short-term stay business, and the recommended charging station may include a charger of the quick charging type.

In some embodiments, the determining a charging type may include determining the charging type as a slow charging type in response to determining that the type of business is a long-term stay business, and the recommended charging station may include a charger of the slow charging type.

In some embodiments, the determining a charging type may include determining the charging type based on the identified type of business and a remaining battery amount of the vehicle.

In some embodiments, the determining a charging type may include determining the charging type as a quick charging type when the identified type of business is a short-term stay business and the remaining battery amount of the vehicle is less than a first value, and the recommended charging station may include a charger of the quick charging type.

In some embodiments, the determining a charging type may include: identifying a charging type preferred by a user based on a user charging pattern when the remaining battery amount of the vehicle is greater than or equal to a second value; and determining the charging type as a charging type preferred by the user.

According to the aforementioned and other embodiments of the present disclosure, there is provided a method for recommending a charging station, which is performed by a computing system, the method may comprise: acquiring a vehicle charging pattern of a user; acquiring a driving route of a vehicle; determining a target sub-section related to a charging station recommendation among a plurality of sub-sections included in the driving route based on the acquired vehicle charging pattern; and providing a user with one or more charging stations located within a predetermined distance from the determined sub-section.

In some embodiments, the determining a target sub-section may include determining a first sub-section from a departure point to a predetermined distance as the target sub-section when a pattern in which a remaining battery amount increases before the vehicle departs for a destination or increases within a critical time after the vehicle departs for the destination is acquired from the vehicle charging pattern.

In some embodiments, the determining a target sub-section may include: acquiring a moving distance until the vehicle is charged, based on the acquired vehicle charging pattern; and determining a target sub-section among the plurality of sub-sections based on the acquired moving distance.

In some embodiments, the charging pattern may be generated based on at least one of a charging station search history of the user or a charging history of the vehicle.

In some embodiments, the determining a target sub-section may include determining a first sub-section from a departure point to a predetermined distance as the target sub-section when a pattern of searching for a charging station before the vehicle departs for a destination is acquired from the vehicle charging pattern.

In some embodiments, the determining a target sub-section may include: acquiring a remaining battery amount of the vehicle in a situation that the user searches for a charging station, based on the acquired vehicle charging pattern; and determining a target sub-section among the plurality of sub-sections based on a sub-section expected to reach the remaining battery amount of the vehicle in a situation that the user searches for a charging station.

In some embodiments, the providing a user with one or more charging stations may include: identifying a charging type preferred by the user based on the vehicle charging pattern; and providing the user with one or more charging stations including a charger of the identified charging type among a plurality of charging stations located within a predetermined distance from the determined sub-section.

According to the aforementioned and other embodiments of the present disclosure, there is provided a navigation device. The navigation device may comprise: one or more processors; and a memory storing one or more instructions, wherein the one or more processors execute the one or more instructions to perform: an operation of identifying a type of business related to a destination of a vehicle corresponding to the navigation device; an operation of determining a charging type based on the identified type of business; an operation of identifying one or more charging stations including a charger of the determined charging type among a plurality of charging stations located within a predetermined distance from the destination of the vehicle; and an operation of providing a user with the identified one or more charging stations as recommended charging stations.

In some embodiments, the operation of determining a charging type may include an operation of determining the charging type as a quick charging type in response to determining that the type of business is a short-term stay business, and the recommended charging station may include a charger of the quick charging type.

In some embodiments, the operation of determining a charging type may include an operation of determining the charging type as a slow charging type in response to determining that the type of business is a long-term stay business, and the recommended charging station may include a charger of the slow charging type.

In some embodiments, the operation of determining a charging type may include an operation of determining the charging type based on the identified type of business and a remaining battery amount of the vehicle.

In some embodiments, the operation of determining a charging type may include an operation of determining the charging type as a quick charging type when the identified type of business is a short-term stay business and the remaining battery amount of the vehicle is less than a first value, and the recommended charging station may include a charger of the quick charging type.

In some embodiments, the operation of determining a charging type may include: an operation of identifying a charging type preferred by a user based on a user charging pattern when the remaining battery amount of the vehicle is greater than or equal to a second value, and an operation of determining the charging type as a charging type preferred by the user.

According to the aforementioned and other embodiments of the present disclosure, there is provided a navigation device. The navigation device may comprise: one or more processors; and a memory storing one or more instructions, wherein the one or more processors execute the one or more instructions to perform: an operation of acquiring a vehicle charging pattern of a user of a vehicle corresponding to the navigation device; an operation of acquiring a driving route of the vehicle; an operation of determining a target sub-section related to a charging station recommendation among a plurality of sub-sections included in the driving route based on the acquired vehicle charging pattern; and an operation of providing a user with one or more charging stations located within a predetermined distance from the determined sub-section.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating a charging station recommendation model according to one embodiment of the present disclosure;

FIG. 2 is a schematic diagram illustrating a charging station recommendation system according to one embodiment of the present disclosure;

FIG. 3 is a block diagram illustrating a charging pattern prediction model according to one embodiment of the present disclosure;

FIG. 4 is a flow chart illustrating a method for recommending a charging station according to one embodiment of the present disclosure;

FIGS. 5 and 6 are detailed flow charts illustrating a method for recommending a charging station according to one embodiment of the present disclosure, which is described with reference to FIG. 4;

FIG. 7 is a flow chart illustrating a method for recommending a charging station according to another embodiment of the present disclosure;

FIGS. 8 to 9 are detailed flow charts illustrating a method for recommending a charging station according to another embodiment of the present disclosure, which is described with reference to FIG. 7;

FIGS. 10 to 13 are exemplary diagrams illustrating an operation of determining a charging station, which may be performed in some embodiments of the present disclosure; and

FIG. 14 is a hardware schematic diagram illustrating a charging station recommendation system according to some embodiments of the present disclosure.

### DETAILED DESCRIPTION OF THE DISCLOSURE

Hereinafter, preferred embodiments of the present disclosure will be described with reference to the attached drawings. Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the present disclosure will only be defined by the appended claims.

In adding reference numerals to the components of each drawing, it should be noted that the same reference numerals are assigned to the same components as much as possible even though they are shown in different drawings. In addition, in describing the present disclosure, when it is determined that the detailed description of the related well-known configuration or function may obscure the gist of the present disclosure, the detailed description thereof will be omitted.

Unless otherwise defined, all terms used in the present specification (including technical and scientific terms) may be used in a sense that can be commonly understood by those skilled in the art. In addition, the terms defined in the commonly used dictionaries are not ideally or excessively interpreted unless they are specifically defined clearly. The terminology used herein is for the purpose of describing particular embodiments only and is not intended to be limiting of the disclosure. In this specification, the singular also includes the plural unless specifically stated otherwise in the phrase.

In addition, in describing the component of this disclosure, terms, such as first, second, A, B, (a), (b), can be used. These terms are only for distinguishing the components from other components, and the nature or order of the components is not limited by the terms. If a component is described as being “connected,” “coupled” or “contacted” to another component, that component may be directly connected to or contacted with that other component, but it should be understood that another component also may be “connected,” “coupled” or “contacted” between each component.

Hereinafter, embodiments of the present disclosure will be described with reference to the attached drawings.

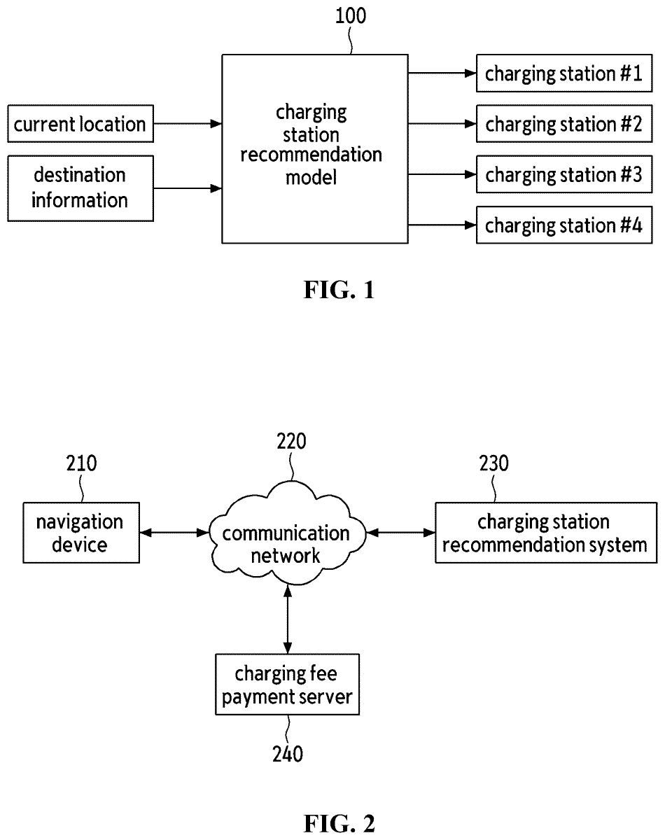

Hereinafter, a configuration and operation of a method for recommending a charging station according to one embodiment of the present disclosure will be described with reference to FIG. 1. FIG. 1 is a block diagram illustrating a charging station recommendation model according to one embodiment of the present disclosure.

As shown in FIG. 1, the method for recommending a charging station may be a method in which a charging station recommendation model 100 that has acquired information on a current location and destination information of a vehicle identifies one or more charging stations and provides the identified one or more recommended charging stations to a user, but the scope of the present disclosure is not limited thereto. In some cases, the method may be a method in which the charging station recommendation model 100 that has acquired one of the current location or the destination information of the vehicle identifies one or more charging stations and provides the identified one or more recommended charging stations to the user. Alternatively, the method may be a method in which the charging station recommendation model 100 that has acquired one or more of the current location and the destination information of the vehicle identifies one charging station and providing the identified one recommended charging station to the user.

Next, FIG. 2 is a schematic diagram illustrating a charging station recommendation system according to one embodiment of the present disclosure.

As shown in FIG. 2, a charging station recommendation system 230 may be connected to a navigation device 210 or a charging fee payment server 240 through a communication network 220 to acquire a current location and destination information of a vehicle, acquire a charging station search history and a vehicle charging history, acquire a vehicle charging pattern of a user, identify a recommended charging station, acquire charging station information and provide the recommended charging station to the user.

The vehicle destination and the current location may be input from the user through the navigation device 210, or may be acquired based on GPS information, but the scope of the present disclosure is not limited thereto.

In some cases, the charging station recommendation system 230 may be included in the navigation device 210 without being connected to the navigation device 210 through the communication network 220. Alternatively, the charging station recommendation system 230 may be connected only to the navigation device 210 through the communication network 220 to acquire the current location and the destination information, and may acquire a charging station search history and a vehicle charging history.

Furthermore, the charging fee payment server 240 may be a charging station management server that acquires and provides a charging station usage history of an individual vehicle, and a current usage status, a failure status and an opening/closing status of the charging station. However, for convenience of description, in the present disclosure, it is assumed that a server that acquires and provides a charging station usage history of an individual vehicle, and a current usage status, a failure status and an opening/closing status of the charging station is a charging fee payment server.

The charging station recommendation system 230 may be connected to the navigation device 210 through the communication network 220 to acquire the current location and the destination information. The charging station recommendation system 230 may identify a type of business related to the acquired destination, and may determine a charging type based on the identified type of business.

Also, the charging station recommendation system 230 may be connected to the navigation device 210 through the communication network 220 to acquire the current location and the destination information. The charging station recommendation system 230 may acquire a vehicle driving route based on the current location, the destination, and the remaining amount of the vehicle, and may determine at least one charging station related to the driving route as a recommended charging station. The navigation device 210 may be connected to the charging station recommendation system 230 through the communication network 220 to acquire determined recommended charging station data and provide the acquired recommended charging station data to the user.

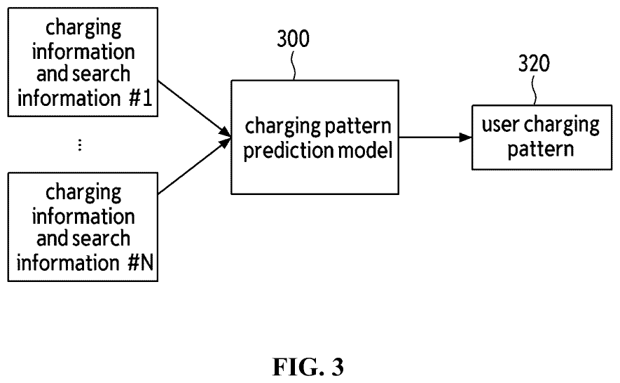

Furthermore, the charging station recommendation system 230 may be connected to the navigation device 210 and the charging charge payment server 240 through the communication network 220 to acquire a charging station search history and a vehicle charging history. The charging station recommendation system 230 may acquire a vehicle charging pattern of the user based on the acquired charging station search history and the vehicle charging history. A method of acquiring a vehicle charging pattern of the user will be described later with reference to FIG. 3.

Furthermore, the charging station recommendation system 230 may be connected to the charging fee payment server 240 through the communication network 220 to acquire information on a plurality of charging stations located within a predetermined distance from the vehicle destination or a plurality of charging stations located within a predetermined distance from the driving route of the vehicle. The predetermined distance may be variously set depending on the embodiment.

In addition, the charging station recommendation system 230 may determine one or more charging stations related to the driving route as recommended charging stations by using the vehicle charging pattern acquired based on the charging station search history and the vehicle charging history, and the type of business related to the identified destination.

FIG. 3 is a block diagram illustrating a charging pattern prediction model according to one embodiment of the present disclosure.

As shown in FIG. 3, a method for predicting a user charging pattern may be a method in which a user charging pattern 320 is acquired based on the charging station search history of the user and the vehicle charging history, which are acquired by the charging pattern prediction model 300.

The charging station search history of the user may include a time point when search is performed, such as before or after the vehicle departs for the destination, or a remaining battery amount of the vehicle in a situation that the charging station is searched. The user charging pattern 320 acquired by the charging pattern prediction model 300 based on the charging station search history of the user may be a pattern that reflects a driving time point at which the user performs charging, and the remaining amount of a battery that the user wants to charge.

The charging pattern prediction model 300 may be included in the charging station recommendation system 230 described with reference to FIG. 2, and the charging station search history of the user may be acquired by the charging station recommendation system 230 connected to the navigation device 210 through the communication network 220.

The charging station charging history of the vehicle may include a time point when search is performed, such as before or after the vehicle departs for the destination, or a remaining battery amount of the vehicle in a situation that charging is performed, and a charger type used to perform the charging. The user charging pattern 320 acquired by the charging pattern prediction model 300 based on the charging station charging history may be a pattern that reflects a driving time point at which the user performs charging, the remaining amount of the battery that the user wants to charge, and a charger type of a charging type preferred by the user, which is a type with the highest frequency of use by the user.

The charging pattern prediction model 300 may be included in the charging station recommendation system 230 described with reference to FIG. 2, and the charging station charging history acquired by the charging pattern prediction model 300 may be acquired by the charging station recommendation system 230 connected to the charging fee payment server 240 through the communication network 220.

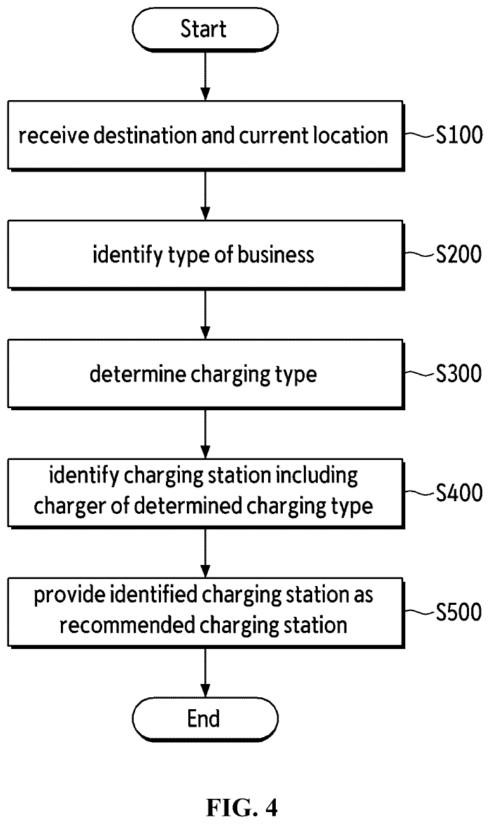

FIG. 4 is a flow chart illustrating a method for recommending a charging station according to one embodiment of the present disclosure. However, this is only a preferred embodiment for achieving the object of the present disclosure, and some steps may be added or deleted as necessary.

As shown in FIG. 4, the charging station recommendation system 230 may receive the destination and the current location of the vehicle (S100). The destination and the current location of the vehicle may be input from the user through the navigation device 210, or may be acquired based on GPS information.

Afterwards, the charging station recommendation system 230 may identify the type of business of the destination based on the received destination information of the vehicle (S200). The charging station recommendation system 230 may predict a time during which the vehicle may perform charging while staying at the destination by identifying the type of business of the destination.

The type of business of the destination may include places expected to stay for a long period of time, such as a hotel, lodging, and residence of a user. Alternatively, the type of business of the destination may include places expected to stay for a short period of time, such as a department store, an outlet, a movie theater, a restaurant, and a work place of a user. Alternatively, the type of business of the destination may include places expected to stay or pass through for an ultra short period of time, such as a distribution warehouse and a convenience store. The scope of the present disclosure is not limited to the above examples.

Afterwards, the charging station recommendation system 230 may determine the charging type based on the identified type of business (S300). The charging type is determined based on a time during which the vehicle may perform charging while staying at the destination. The charging station recommendation system 230 may determine a quick charging type as the charging type to perform quick charging when it is predicted that the vehicle will stay at the destination for a short period of time. Alternatively, the charging station recommendation system 230 may determine a slow charging type as the charging type to perform slow charging when it is predicted that the vehicle will stay at the destination for a long period of time.

Afterwards, the charging station recommendation system 230 may identify a charging station including a charger of the determined charging type (S400). The charging station recommendation system 230 may determine, as the charging type, a quick charger when the determined charging type is a quick charging type, an ultra-quick charger when the determined charging type is an ultra-quick charging type, and a slow charger when the determined charging type is a slow charging type.

The charging station recommendation system 230 may identify one or more charging stations including a charger of the determined charging type among a plurality of charging stations located within a predetermined distance from the destination of the vehicle. The charging station recommendation system 230 may acquire information on a plurality of charging stations located within a predetermined distance from the charging fee payment server 240 connected through the communication network 220. The charging station recommendation system 230 may identify a charging station including a charger of the determined charging type among the plurality of charging stations located within the predetermined distance based on the acquired information on the plurality of charging stations located within the predetermined distance.

Afterwards, the charging station recommendation system 230 may provide the identified charging station as a recommended charging station (S500). The charging station recommendation system 230 may provide the identified charging station, as a recommended charging station, to the navigation device 210 connected through the communication network 220.

According to the present embodiment, the type of business of the destination may be identified and the charging station may be provided in accordance with the corresponding type, so that the purpose of visiting the destination may be reflected in the use of the charging station. For example, since proper slow charging is required to protect the battery life of the vehicle, a charging station including a slow charger when the vehicle is scheduled to stay for a long period of time may be recommended to protect the battery life of the vehicle. Alternatively, a quick charger or an ultra-quick charger may be recommended to obtain the maximum charging efficiency in a short-term stay situation, so that a stable driving experience may be provided to a user.

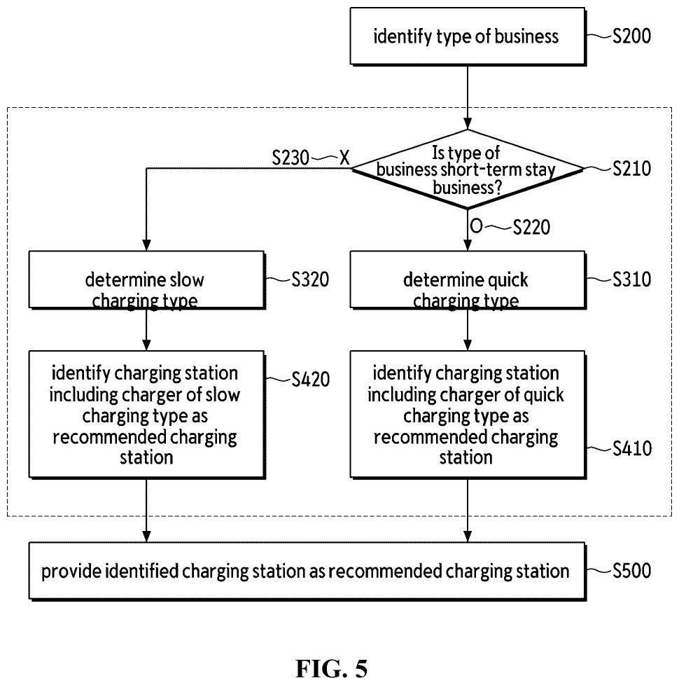

Next, the method for recommending a charging station by identifying a type of business of a destination and determining a charging type in accordance with one embodiment of the present disclosure, which is described with reference to FIG. 4, will be described in detail with reference to FIG. 5.

As shown in FIG. 5, in the step S200 of identifying the type of business, the charging station recommendation system 230 may identify whether the type of business of the destination is a short-term stay business (S210). The short-term stay business is, for example, a business in which it is determined that a user will stay for a short period of time, such as a cafe, a movie theater, and a store. As a long-term stay business not the short-term stay business, there are businesses in which it is determined that a user will stay for a long period of time, such as lodging, home, and company.

The charging station recommendation system 230 may determine the quick charging type as the charging type to perform quick charging (S310) when the vehicle is identified to stay at the destination for a short period of time (S220), and may determine the slow charging type as the charging type to perform slow charging (S320) when the vehicle is identified to stay at the destination for a long period of time (S230).

When the quick charging type is determined as the charging type, the charging station recommendation system 230 may acquire information on a plurality of charging stations located within a predetermined distance and identify a charging station including a charger of a quick charging type among the acquired charging stations as a recommended charging station (S410). When the slow charging type is determined as the charging type, the charging station recommendation system 230 may acquire information on the plurality of charging stations located within the predetermined distance and identify a charging station including a charger of the slow charging type among the acquired charging stations as a recommended charging station (S420).

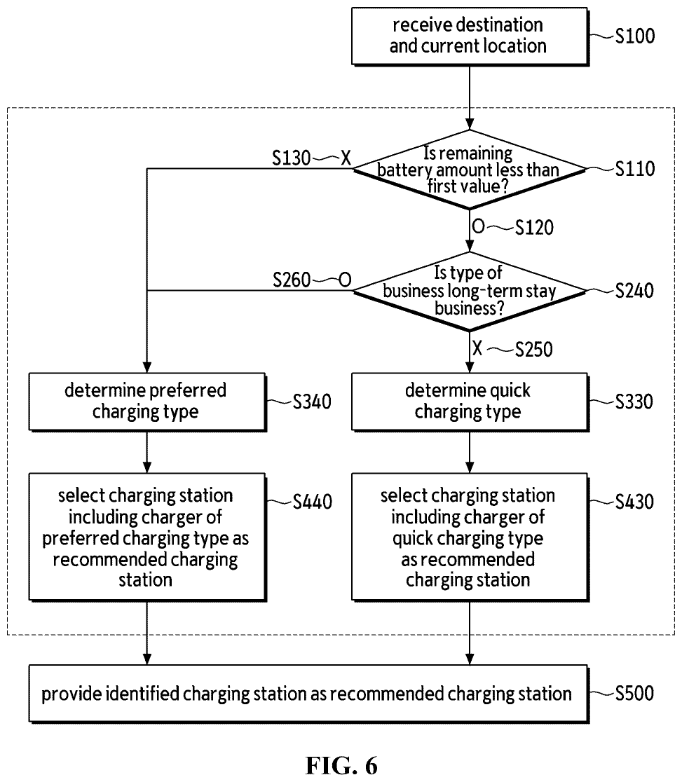

Next, the method for recommending a charging station by reflecting a remaining battery amount in accordance with another embodiment of the present disclosure, which is described with reference to FIG. 4, will be described in detail with reference to FIG. 6.

As shown in FIG. 6, the charging station recommendation system 230 may acquire a remaining battery amount of the vehicle and determine whether the corresponding value is less than a first value (S110). The first value may be variously set depending on the embodiment. For example, the first value may be an average remaining battery amount of the vehicle when a user performs charging. Alternatively, the first value may be a remaining battery amount of the vehicle that maintains the battery life efficiency of the vehicle.

When it is determined that the remaining battery amount of the vehicle is less than the first value (S120), the charging station recommendation system 230 may identify whether the type of business of the destination is a long-term stay business (S240). When it is identified that the vehicle will not stay at the destination for a long period of time (S250), the charging station recommendation system 230 may determine the quick charging type as the charging type to perform quick charging (S330). When the quick charging type is determined as the charging type, the charging station recommendation system 230 may acquire information on a plurality of charging stations located within a predetermined distance and select a charging station including a charger of the quick charging type among the acquired charging stations as a recommended charging station (S430).

When it is determined that the remaining battery amount of the vehicle is less than the first value (S120), the charging station recommendation system 230 may identify whether the type of business of the destination is a long-term stay business (S240). When it is identified that the vehicle will stay at the destination for a long period of time (S260), the charging station recommendation system 230 may determine a preferred charging type as the charging type to perform the charging type preferred by the user (S340). When the user preferred charging type is determined as the charging type, the charging station recommendation system 230 may acquire information on the plurality of charging stations located within a predetermined distance and select a charging station including a charger of the preferred charging type as a recommended charging station (S440).

The user preferred charging type is a charging type determined to be preferred by the user based on the user charging pattern, and may be a charging type preferred by the user between a quick charger and a slow charger.

When the remaining battery amount of the vehicle is determined to be equal to or greater than the first value (S130), the charging station recommendation system 230 may determine the preferred charging type as the charging type to perform charging preferred by the user (S340). When the user preferred charging type is determined as the charging type, the charging station recommendation system 230 may acquire information on the plurality of charging stations located within a predetermined distance, and may select a charging station including a charger of the preferred charging type among the acquired charging stations as a recommended charging station (S440).

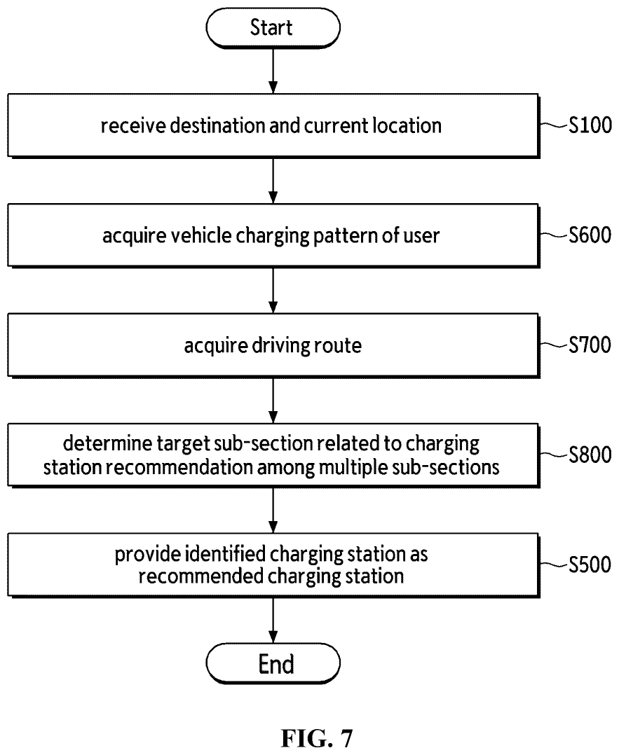

FIG. 7 is a flow chart illustrating a method for recommending a charging station according to another embodiment of the present disclosure;

As shown in FIG. 7, the charging station recommendation system 230 may receive the destination and the current location of the vehicle (S100). The destination and the current location of the vehicle may be input from the user through the navigation device 210, or may be acquired based on GPS information.

Afterwards, the charging station recommendation system 230 may acquire a vehicle charging pattern of the user (S600). As described with reference to FIG. 3, the charging pattern of the user may be generated based on at least one of a charging station search history of the user or a vehicle charging history. The charging station recommendation system 230 may be connected to the navigation device 210 or the charging fee payment server 240 through the communication network 220 to acquire the charging station search history and the vehicle charging history and acquire the vehicle charging pattern of the user.

The charging station recommendation model 100 may acquire the vehicle charging pattern of the user, which reflects charging performed before moving, when the charging history of the vehicle of which remaining battery amount increases within a critical time before or after the navigation device starts guiding to a destination. For example, the charging station recommendation model 100 that has acquired the charging history of the vehicle of which remaining battery amount increases within a critical time before or after the navigation device starts guiding to a destination may generate the charging pattern of the user by reflecting a charging station at the beginning of the driving route as a recommended charging station.

When the charging station recommendation model 100 acquires the charging history of the vehicle of which remaining battery amount increases after a critical time after the navigation device starts guiding to a destination, the charging station recommendation model 100 may acquire the vehicle charging pattern of the user, which reflects charging performed while moving. For example, the charging station recommendation model 100, which has acquired the charging history of the vehicle of which remaining battery amount increases after a critical time after the navigation device starts guiding to a destination, may generate the charging pattern of the user by reflecting a charging station at the end of the driving route as a recommended charging station.

The charging station recommendation model 100 may acquire a vehicle charging pattern of the user, which reflects a first moving distance that is a moving distance until the vehicle is charged. For example, the charging station recommendation model 100 may generate the charging pattern of the user by reflecting a charging station located at a location spaced apart from the current position by the first moving distance as a recommended charging station.

The charging station recommendation model 100 may acquire a vehicle charging pattern of the user, which reflects a first remaining battery amount at which a remaining battery amount of the vehicle increases. For example, the charging station recommendation model 100 may generate the charging pattern of the user by reflecting a charging station, which is located at a location spaced apart by a distance from which the current remaining battery amount of the vehicle is expected to reach the first remaining battery amount, as a recommended charging station.

The charging station recommendation model 100 may acquire the user's vehicle charging pattern reflecting charging performed before moving when the charging station search history of the user is acquired within a critical time before or after the navigation device starts guiding to a destination. For example, the charging station recommendation model 100, which has acquired the charging history of the vehicle of which remaining battery amount increases within a critical time after or before the navigation device starts guiding to a destination, may generate the charging pattern of the user by reflecting the charging station at the beginning of the driving route as a recommended charging station.

When the charging station search history of the user is acquired after a critical time after the navigation device starts guiding to a destination, the charging station recommendation model 100 may acquire the vehicle charging pattern of the user, which reflects charging performed while moving. For example, the charging station recommendation model 100, which has acquired the charging history of the vehicle of which remaining battery amount increases after the critical time after the navigation device starts guiding to a destination, may generate the charging pattern of the user by reflecting the charging station at the end of the driving route as a recommended charging station.

The charging station recommendation model 100 may acquire a vehicle charging pattern of the user, which reflects the first moving distance at which the user's search for a charging station occurs. For example, the charging station recommendation model 100 may generate a charging pattern of the user by reflecting a charging station located at a location spaced apart from the current position by the first moving distance as a recommended charging station.

The charging station recommendation model 100 may acquire the vehicle charging pattern of the user, which reflects the first remaining battery amount at which the user's search for a charging station occurs. For example, the charging station recommendation model 100 may generate the charging pattern of the user by reflecting a charging station located at a location spaced apart by a distance from which the current remaining battery amount of the vehicle is expected to reach the first remaining battery amount as a recommended charging station.

Afterwards, the charging station recommendation system 230 may acquire a driving route (S700). The driving route may be a route that starts from a current location and reaches a destination. The driving route may be determined by reflecting a traffic situation, a preferred road of the user, a time required when using the route, an amount required when using the route, power required when using the route, and the like. The driving route may include a plurality of sub-sections. Each of the plurality of sub-sections may be configured to have a predefined distance.

Afterwards, the charging station recommendation system 230 may determine a target sub-section, which is one sub-section related to the charging station recommendation, among the plurality of sub-sections (S800). The charging station recommendation system 230 may determine one or more charging stations located within a predetermined distance from the determined target sub-section as a recommended charging station. The target sub-section related to the charging station recommendation may be determined based on the vehicle charging pattern of the user.

For example, when the charging station recommendation system 230 generates the charging pattern of the user by reflecting the charging station at the beginning of the driving route as a recommended charging station, the charging station recommendation system 230 may determine the initial section of the plurality of sub-sections as the target sub-section.

Alternatively, when the charging station recommendation system 230 generates the charging pattern of the user by reflecting the charging station at the end of the driving route as a recommended charging station, the charging station recommendation system 230 may determine the second half section of the plurality of sub-sections may be determined as the target sub-section.

Alternatively, when the charging station recommendation system 230 generates the charging pattern of the user by reflecting a charging station located at a location spaced apart from the current location by the first moving distance as a recommended charging station, the charging station recommendation system 230 may determine the section spaced apart from the current location by the first moving distance among the plurality of sub-sections as a target sub-section.

Alternatively, when the charging station recommendation system 230 generates the charging pattern of the user by reflecting the charging station located at a location spaced apart by a distance that the current remaining battery amount of the vehicle is expected to reach the first remaining battery amount as a recommended charging station, the charging station recommendation system 230 may determine a section, which is spaced apart from the current location by the distance that the current remaining battery amount of the vehicle is expected to reach the first battery remaining amount, among the plurality of sub-sections as a target sub-section.

Afterwards, the charging station recommendation system 230 may provide the identified charging station as a recommended charging station (S500). The charging station recommendation system 230 may provide the identified charging station to the navigation device 210 connected through the communication network 220 as a recommended charging station.

According to the present embodiment, the vehicle charging pattern of the user may be acquired and the charging station may be recommended in accordance with the corresponding pattern, so that a satisfactory driving experience reflecting the needs of an individual user may be provided.

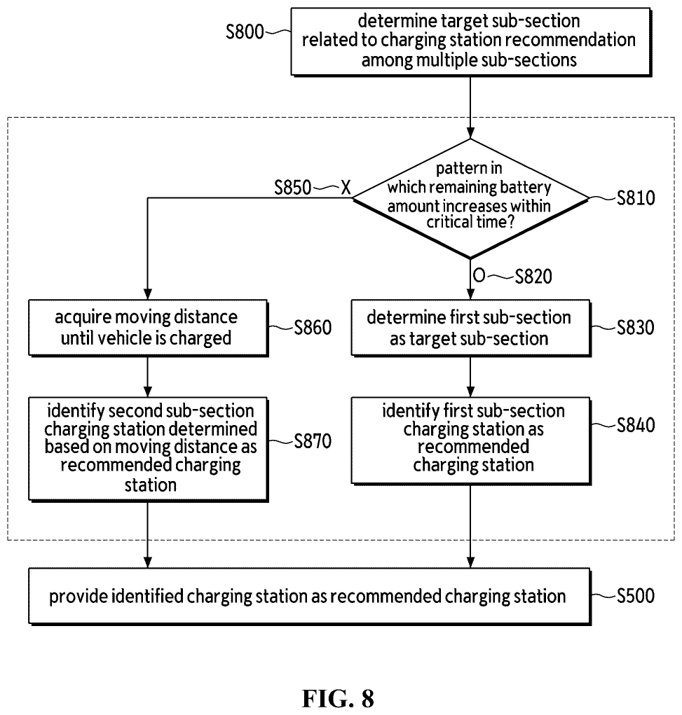

Next, the method for recommending a charging station by determining a pattern in accordance with one embodiment of the present disclosure, which is described with reference to FIG. 7, will be described in detail with reference to FIG. 8.

As shown in FIG. 8, in the step of determining a target sub-section, which is one sub-section related to the charging station recommendation, among the plurality of sub-sections, the charging station recommendation system 230 may determine whether the vehicle charging pattern of the user is a pattern in which the remaining battery amount increases within a critical time (S810). When the vehicle charging pattern of the user is the pattern in which the remaining battery amount increases within the critical time (S820), the charging station recommendation system 230 may determine a first sub-section, which is a section from a departure point to a predetermined distance, as a target sub-section (S830), and may identify the charging station included in the first sub-section as a recommended charging station (S840).

Alternatively, when the vehicle charging pattern of the user is not the pattern in which the remaining battery amount increases within the critical time (S850), the charging station recommendation system 230 may acquire a first moving distance where the remaining battery amount of the vehicle has increased (S860), and may identify a charging station included in a second sub-section, which is within a predetermined range from a section spaced apart from the current location by the first moving distance, as a recommended charging station (S870).

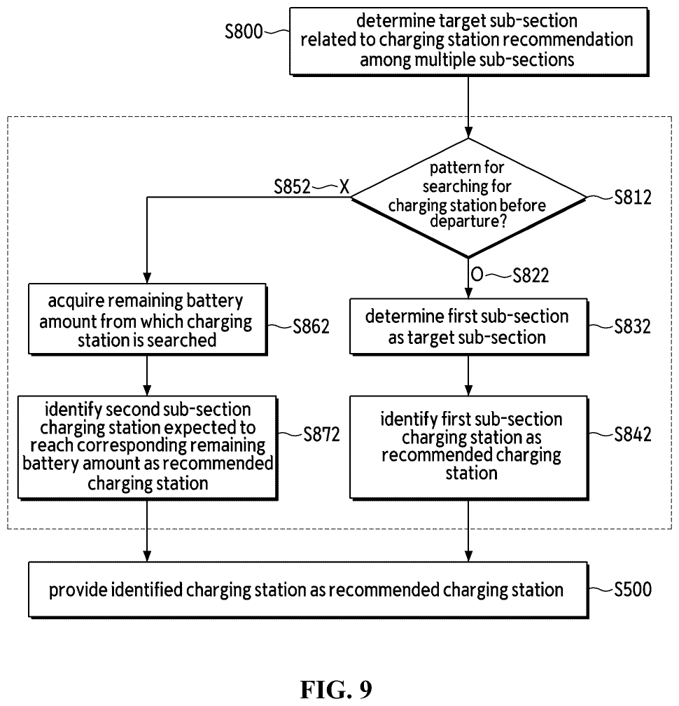

Next, another method for recommending a charging station by determining a pattern in accordance with one embodiment of the present disclosure, which is described with reference to FIG. 7, will be described in detail with reference to FIG. 9.

As shown in FIG. 9, in the step of determining a target sub-section, which is one sub-section related to the charging station recommendation, among the plurality of sub-sections, the charging station recommendation system 230 may determine whether the vehicle charging pattern of the user is a pattern for searching for a charging station before departure (S812). When the vehicle charging pattern of the user is the pattern of searching for a charging station before departure (S822), the charging station recommendation system 230 may determine the first sub-section, which is a section from the departure point to the predetermined distance, as a target sub-section (S832), and may identify the charging station included in the first sub-section as a recommended charging station (S842).

Alternatively, the charging station recommendation system 230 may acquire the remaining battery amount from which the charging station is searched (S862) when the vehicle charging pattern of the user is not the pattern of searching for the charging station before departure (S852), and may identify the charging station of the second sub-section, which is expected to reach the remaining battery amount at the current location, as a recommended charging station (S872).

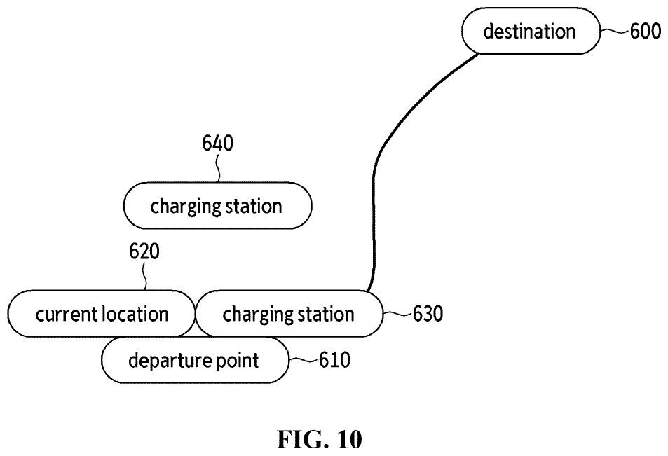

Next, FIGS. 10 to 13 are exemplary diagrams illustrating an operation of determining a recommended charging station, which may be performed in some embodiments of the present disclosure.

As shown in FIG. 10, the charging station recommendation system 230 may receive a destination 600, a current location 620 and a departure point 610 of the vehicle. The destination 600, the departure point 610 and the current location 620 of the vehicle may be input from the user through the navigation device 210, or may be acquired based on GPS information.

The charging station recommendation system 230 may be connected to the navigation device 210 or the charging fee payment server 240 through the communication network 220 to acquire a charging station search history and a vehicle charging history, and may acquire a vehicle charging pattern of the user.

Afterwards, the charging station recommendation system 230 may acquire a driving route. The driving route may be a route from the departure point 610 to the destination 600. The driving route may be determined by reflecting a traffic situation, a preferred road of the user, a time required when using the route, an amount required when using the route, power required when using the route, and the like. The driving route may include a plurality of sub-sections. Each of the plurality of sub-sections may be configured to have a predefined distance.

The charging station recommendation system 230 may determine one or more charging stations located within a predetermined distance from the determined target sub-section as recommended charging stations. The charging station recommendation system 230, which has acquired the user's vehicle charging pattern reflecting charging performed before moving, may determine the initial section of the plurality of sub-sections as the target sub-section. The target sub-section related to the charging station recommendation may be determined based on the vehicle charging pattern of the user.

For example, the charging station recommendation model 100 may acquire the user's vehicle charging pattern reflecting charging performed before moving, when the charging history of the vehicle of which remaining battery amount increases is acquired within the critical time before or after the navigation device starts guiding to the destination 600. Alternatively, the charging station recommendation model 100 may acquire the user's vehicle charging pattern reflecting charging performed before moving, when the charging station search history is acquired within the critical time before or after the navigation device starts guiding to the destination 600.

The charging station recommendation system 230, which has acquired the user's vehicle charging pattern reflecting charging performed before moving, may divide the driving route from the current location 620 to the destination 600 into a plurality of sub-sections, and may determine an initial section close to the departure point 610 as a target sub-section. The charging station recommendation system 230 determining the target sub-section may determine the charging station 630 and the charging station 640, which are located within a predetermined distance from the target sub-section, as recommended charging stations.

The charging station recommendation system 230 determining the charging station 630 and the charging station 640 as recommended charging stations may determine the preferred charging type as the charging type to perform charging preferred by the user. The charging station recommendation system 230 determining the charging preferred by the user as the charging type may determine the charging station 640, which includes more chargers corresponding to the charging type preferred by the user, between the charging station 630 and the charging station 640 as the recommended charging station.

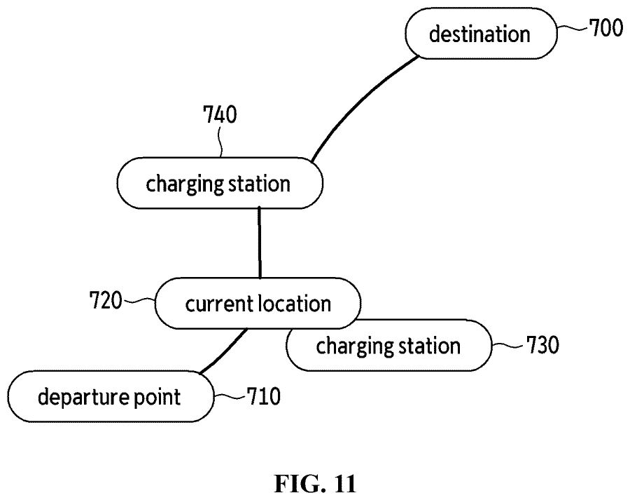

As shown in FIG. 11, the vehicle charging pattern of the user, which is acquired by the charging station recommendation system 230, may receive a destination 700, a current location 720 and a departure point 710 of the vehicle.

Afterwards, the charging station recommendation system 230 may acquire a driving route. The driving route may be a route from the departure point 710 to the destination 700. The driving route may be determined by reflecting a traffic situation, a preferred road of the user, a time required when using the route, an amount required when using the route, power required when using the route, and the like. The driving route may include a plurality of sub-sections. Each of the plurality of sub-sections may be configured to have a predefined distance.

The charging station recommendation system 230 may determine one or more charging stations located within a predetermined distance from the determined target sub-section as recommended charging stations. The charging station recommendation system 230 may generate the charging pattern of the user by reflecting a charging station located at a location spaced apart from the current location by the first moving distance as a recommended charging station. The charging station recommendation system 230, which has acquired the user's vehicle charging pattern reflecting the first moving distance where the remaining battery amount of the vehicle increases and the charging station search of the user occurs, may determine the section spaced apart from the departure point 710 by the first moving distance as the target sub-section. The target sub-section related to the charging station recommendation may be determined based on the vehicle charging pattern of the user.

For example, the charging station recommendation model 100 may acquire the user's vehicle charging pattern reflecting the first moving distance where the remaining battery amount of the vehicle increases. Alternatively, the charging station recommendation model 100 may acquire the user's vehicle charging pattern reflecting the first moving distance where the charging station search of the user occurs. The charging station recommendation model 100 may generate the charging pattern of the user by reflecting a charging station located at a location spaced apart from the departure point 710 by the first moving distance as a recommended charging station.

The charging station recommendation system 230, which has acquired the user's vehicle charging pattern reflecting the first moving distance where the remaining battery amount of the vehicle increases, may divide the driving route from the departure point 710 to the destination 700 into a plurality of sub-sections, and may determine a section spaced apart from the departure point 710 by the first moving distance as a target sub-section. The charging station recommendation system 230 determining the target sub-section may determine the charging station 740, which is located within a predetermined distance from the target sub-section rather than the nearby charging station 730, as a recommended charging station.

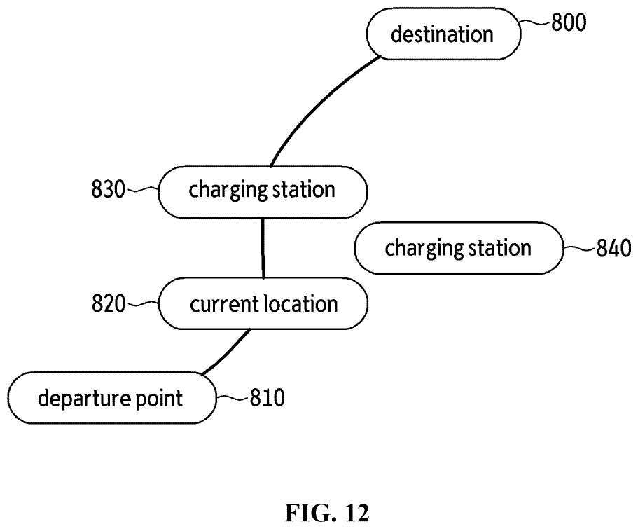

As shown in FIG. 12, the vehicle charging pattern of the user, which is acquired by the charging station recommendation system 230, may receive a destination 800, a current location 820 and a departure point 810 of the vehicle.

Afterwards, the charging station recommendation system 230 may acquire a driving route. The driving route may be a route from the departure point 810 to the destination 800. The driving route may be determined by reflecting a traffic situation, a preferred road of the user, a time required when using the route, an amount required when using the route, power required when using the route, and the like. The driving route may include a plurality of sub-sections. Each of the plurality of sub-sections may be configured to have a predefined distance.

The charging station recommendation system 230 may determine one or more charging stations located within a predetermined distance from the determined target sub-section as recommended charging stations. The charging station recommendation system 230 may generate the charging pattern of the user by reflecting the remaining amount of the battery that the user wants to charge. The charging station recommendation system 230, which has acquired the user's vehicle charging pattern reflecting a first remaining battery amount at which the remaining battery amount of the vehicle increases, may determine a section, which is spaced apart from the departure point 810 by a distance where the remaining battery amount of the vehicle is expected to reach the first remaining battery amount, as the target sub-section. The target sub-section related to the charging station recommendation may be determined based on the vehicle charging pattern of the user.

For example, the charging station recommendation model 100 may acquire the user's vehicle charging pattern reflecting the first remaining battery amount where the remaining battery amount of the vehicle increases. Alternatively, the charging station recommendation model 100 may acquire the user's vehicle charging pattern reflecting the first remaining battery amount at which the charging station search of the user occurs. The charging station recommendation model 100 may generate the charging pattern of the user by reflecting a charging station located at a location spaced apart from the departure point 810 by a distance where the remaining battery amount of the vehicle is expected to reach the first remaining battery amount, as the target sub-section.

The charging station recommendation system 230, which has acquired the user's vehicle charging pattern reflecting the distance where the remaining battery amount of the vehicle is expected to reach the first remaining battery amount, may divide the driving route from the departure point 810 to the destination 800 into a plurality of sub-sections, and may determine a section spaced apart from the departure point 810 by the distance where the remaining battery amount of the vehicle is expected to reach the first remaining battery amount, as the target sub-section. The charging station recommendation system 230 that has determined the target sub-section may determine the charging station 840, which is located within a predetermined distance from the target sub-section rather than the charging station 830 closest to the route, as a recommended charging station.

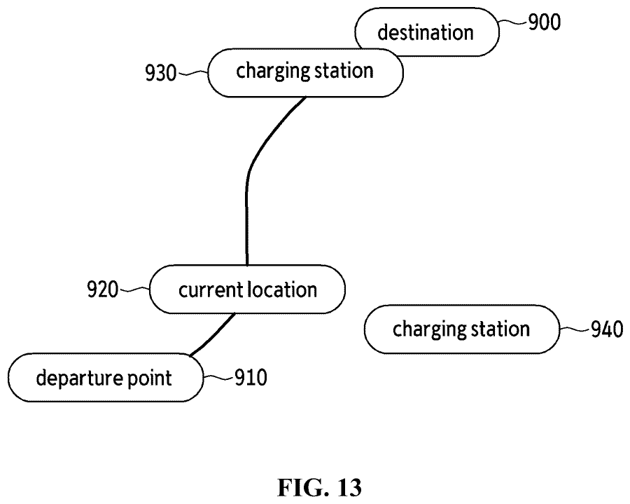

As shown in FIG. 13, the vehicle charging pattern of the user, which is acquired by the charging station recommendation system 230, may receive a destination 900, a current location 920 and a departure point 910 of the vehicle.

Afterwards, the charging station recommendation system 230 may acquire a driving route. The driving route may be a route from the departure point 910 to the destination 900. The driving route may be determined by reflecting a traffic situation, a preferred road of the user, a time required when using the route, an amount required when using the route, power required when using the route, and the like. The driving route may include a plurality of sub-sections. Each of the plurality of sub-sections may be configured to have a predefined distance.

The charging station recommendation system 230 may determine one or more charging stations located within a predetermined distance from the determined target sub-section as recommended charging stations. The charging station recommendation system 230 may acquire the charging pattern of the user by reflecting charging after the critical time after the navigation device starts guiding to a destination. The charging station recommendation system 230, which has acquired the user's vehicle charging pattern performing charging after the critical time after the navigation device starts guiding to a destination, may determine the second half section of the plurality of sub-sections as the target sub-section. The target sub-section related to the charging station recommendation may be determined based on the vehicle charging pattern of the user. For example, the charging station recommendation model 100 may acquire the user's vehicle charging pattern reflecting charging performed while moving, when the charging history of the vehicle of which remaining battery amount increases is acquired after the critical time after the navigation device starts guiding to the destination 900. Alternatively, the charging station recommendation model 100 may acquire the user's vehicle charging pattern reflecting charging performed before moving, when the charging station search history is acquired after the critical time after the navigation device starts guiding to the destination 900.

The charging station recommendation system 230, which has acquired the user's vehicle charging pattern reflecting charging performed while moving, may divide the driving route from the departure point 910 to the destination 900 into a plurality of sub-sections, and may determine a section close to the destination 900 rather than the sub-section close to the current location 920 as the target sub-section. The charging station recommendation system 230 determining the target sub-section may determine the charging station 930, which is located within a predetermined distance from the target sub-section, as a recommended charging station.

Alternatively, the charging station recommendation system 230 may determine a charging type based on the identified type of business related to the vehicle destination 900, and may determine one or more charging stations related to the driving route as recommended charging stations.

The charging station recommendation system 230 may receive the destination 900 and the current location 920 of the vehicle. The destination, the current location 920 and the departure point 910 of the vehicle may be input from the user through the navigation device 210, or may be acquired based on GPS information.

Afterwards, the charging station recommendation system 230 may identify the type of business of the destination based on the received information on the destination of the vehicle. The charging station recommendation system 230 may predict a time during which the vehicle may perform charging while staying at the destination, by identifying the type of business of the destination.

The type of business of the destination may include places expected to stay for a long period of time, such as a hotel, lodging, and residence of the user. Alternatively, the type of business of the destination may include places expected to stay for a short period of time, such as a department store, an outlet, a movie theater, a restaurant, and a user's workplace. Alternatively, the type of business of the destination may include places expected to stay or pass through for an ultra short period of time, such as a distribution warehouse and a convenience store.

Afterwards, the charging station recommendation system 230 may determine the charging type based on the identified type of business. The charging type is determined based on the time during which the vehicle may perform charging while staying at the destination. When it is predicted that the vehicle will stay at the destination for a short period of time, the charging station recommendation system 230 may determine the quick charging type as the charging type to perform quick charging. Alternatively, when it is predicted that the vehicle will stay at the destination for a long period of time, the charging station recommendation system 230 may determine the slow charging type as the charging type to perform slow charging.

Afterwards, the charging station recommendation system 230 may identify a charging station including a charger of the determined charging type. The charging station recommendation system 230 may determine a quick charger when the determined charging type is a quick charging type, an ultra-quick charger when the determined charging type is an ultra-quick charging type, and a slow charger when the determined charging type is a slow charging type.

The charging station recommendation system 230 may identify one or more charging stations including a charger of the determined charging type among a plurality of charging stations located within a predetermined distance from the destination of the vehicle. The charging station recommendation system 230 may acquire information on the plurality of charging stations located within a predetermined distance from the charging fee payment server 240 connected through the communication network 220. The charging station recommendation system 230 may identify a charging station including a charger of the determined charging type among the plurality of charging stations located within the predetermined distance based on the acquired information on the plurality of charging stations located within the predetermined distance.

Afterwards, the charging station recommendation system 230 may provide the identified charging station as a recommended charging station. The charging station recommendation system 230 may provide the identified charging station to the navigation device 210 connected through the communication network 220 as a recommended charging station.

For example, the charging station recommendation model 100 may identify that the destination 900 is a hotel and the type of business of the destination 900 is a long-term stay business based on the received information on the destination of the vehicle. The charging station recommendation system 230 may determine the slow charging type as the charging type based on that the type of business of the destination 900 is the long-term stay business. The charging station recommendation system 230 may determine the slow charger as the charger of the charging type based on that the slow charging type is determined as the charging type.

Afterwards, the charging station recommendation system 230 may identify a plurality of charging stations located within a predetermined distance from the destination 900 of the vehicle. The charging station recommendation system 230 may acquire information on the plurality of charging stations located within a predetermined distance from the charging fec payment server 240 connected through the communication network 220. Afterwards, the charging station recommendation system 230 may provide the charging station 930 identified as including the slow charger, as the recommended charging station, based on the information on the plurality of charging stations.

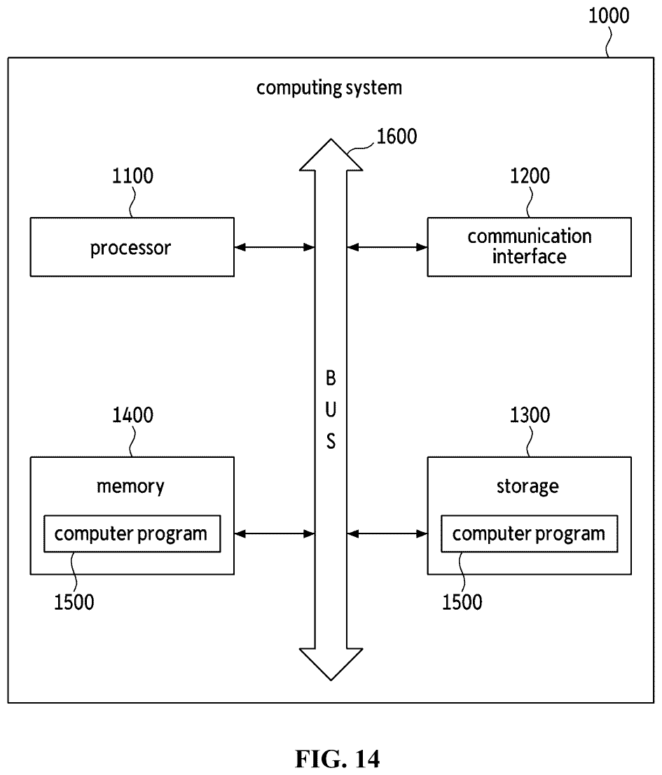

FIG. 14 is a hardware schematic view illustrating a charging station recommendation system according to some embodiments of the present disclosure. The computing system 1000 shown in FIG. 14 may include one or more processors 1100, a system bus 1600, a communication interface 1200, and a memory 1400 for loading a computer program 1500 performed by the processor 1100, and a storage 1300 for storing the computer program 1500.

The processor 1100 controls the overall operation of each component of the computing system 1000. The processor 1100 may perform an operation for at least one application or program for executing methods/operations according to various embodiments of the present disclosure. The memory 1400 stores various data, commands, and/or information. The memory 1400 may load one or more computer programs 1500 from the storage 1300 to execute the methods/operations according to various embodiments of the present disclosure. The system bus 1600 provides a communication function between components of the computing system 1000. The communication interface 1200 supports Internet communication of the computing system 1000. The communication interface 1200 may receive driving information of a vehicle in real time by being connected to an electronic control unit (ECU) of the vehicle through a controller area network (CAN).

The storage 1300 may non-temporarily store one or more computer programs 1500. The computer program 1500 may include one or more instructions in which the methods/operations according to various embodiments of the present disclosure are implemented. When the computer program 1500 is loaded into the memory 1400, the processor 1100 may perform the methods/operations according to various embodiments of the present disclosure by executing the one or more instructions.

In some embodiments, the computing system 1000 described with reference to FIG. 14 may be configured using one or more physical servers included in a server farm based on a cloud technology such as a virtual machine. In this case, at least a portion of the processor 1100, the memory 1400, and the storage 1300 among the components shown in FIG. 14 may be virtual hardware, and the communication interface 1200 may also be configured as a virtualized networking element such as a virtual switch.

The computer program 1500 may include instructions for performing an operation of identifying a type of business related to a destination of a vehicle corresponding to a navigation device of the computing system 100, an operation of determining a charging type based on the identified type of business, an operation of identifying one or more charging stations including a charger of the determined charging type among a plurality of charging stations located within a predetermined distance from the destination of the vehicle, and an operation of providing the identified one or more charging stations to a user as recommended charging stations.

So far, a variety of embodiments of the present disclosure and the effects according to embodiments thereof have been mentioned with reference to FIGS. 1 to 14. The effects according to the technical idea of the present disclosure are not limited to the forementioned effects, and other unmentioned effects may be clearly understood by those skilled in the art from the description of the specification.

The technical features of the present disclosure described so far may be embodied as computer readable codes on a computer readable medium. The computer readable medium may be, for example, a removable recording medium (CD, DVD, Blu-ray disc, USB storage device, removable hard disk) or a fixed recording medium (ROM, RAM, computer equipped hard disk). The computer program recorded on the computer readable medium may be transmitted to other computing device via a network such as internet and installed in the other computing device, thereby being used in the other computing device.

Although operations are shown in a specific order in the drawings, it should not be understood that desired results can be obtained when the operations must be performed in the specific order or sequential order or when all of the operations must be performed. In certain situations, multitasking and parallel processing may be advantageous. According to the above-described embodiments, it should not be understood that the separation of various configurations is necessarily required, and it should be understood that the described program components and systems may generally be integrated together into a single software product or be packaged into multiple software products.

In concluding the detailed description, those skilled in the art will appreciate that many variations and modifications can be made to the preferred embodiments without substantially departing from the principles of the present disclosure. Therefore, the disclosed preferred embodiments of the disclosure are used in a generic and descriptive sense only and not for purposes of limitation.

What is claimed is:

1. A method for recommending a charging station, which is performed by a computing system, the method comprising:
identifying a type of business related to a destination of a vehicle;
determining a charging type based on the type of business;
identifying at least one charging station including a charger of the charging type among a plurality of charging stations located within a predetermined distance from the destination of the vehicle; and
providing a user with the at least one charging station as recommended charging stations.

2. The method of claim 1, wherein the determining of the charging type includes determining the charging type as a quick charging type in response to determining that the type of business is a short-term stay business, and
wherein the recommended charging stations include a charger of the quick charging type.

3. The method of claim 1, wherein the determining of the charging type includes determining the charging type as a slow charging type in response to determining that the type of business is a long-term stay business, and
Wherein the recommended charging stations include a charger of the slow charging type.

4. The method of claim 1, wherein the determining of the charging type includes determining the charging type based on the type of business and a remaining battery amount of the vehicle.

5. The method of claim 4, wherein the determining of the charging type includes determining the charging type as a quick charging type when the type of business is a short-term stay business and the remaining battery amount of the vehicle is less than a first value, and
wherein the recommended charging stations includes a charger of the quick charging type.

6. The method of claim 4, wherein the determining of the charging type includes:
identifying a preferred charging type of the user based on a user charging pattern when the remaining battery amount of the vehicle is more than a second value; and
determining the charging type as the preferred charging type of the user.

7. A method for recommending a charging station, which is performed by a computing system, the method comprising:
acquiring a vehicle charging pattern of a user;
acquiring a driving route of a vehicle;
determining a target sub-section related to a charging station recommendation among a plurality of sub-sections included in the driving route based on the vehicle charging pattern of the user; and
providing the user with at least one charging station located within a predetermined distance from the target sub-section.

8. The method of claim 7, wherein the determining of the target sub-section includes determining a first sub-section located at a predetermined distance from a departure point as the target sub-section when a pattern in which a remaining battery amount increases before the vehicle departs for a destination or the remaining battery amount increases within a critical time after the vehicle departs for the destination is acquired from the vehicle charging pattern.

9. The method of claim 7, wherein the determining of the target sub-section includes:
acquiring a moving distance until the vehicle is charged based on the vehicle charging pattern of the user; and
determining the target sub-section among the plurality of sub-sections based on the moving distance.

10. The method of claim 7, wherein the vehicle charging pattern is generated based on a charging station search history of the user or a charging history of the vehicle.

11. The method of claim 7, wherein the determining of the target sub-section includes determining a first sub-section located at a predetermined distance from a departure point as the target sub-section when a pattern of searching for a charging station before the vehicle departs for a destination is acquired from the vehicle charging pattern.

12. The method of claim 7, wherein the determining of the target sub-section includes:
acquiring a remaining battery amount of the vehicle in a situation that the user searches for a charging station based on the vehicle charging pattern of the user; and
determining the target sub-section among the plurality of sub-sections based on a sub-section expected to reach the remaining battery amount of the vehicle in a situation that the user searches for the charging station.

13. The method of claim 7, wherein the providing the user with the at least one charging station includes:
identifying a charging type preferred by the user based on the vehicle charging pattern; and
providing the user with the at least one charging station including a charger of the charging type among a plurality of charging stations located within the predetermined distance from the target sub-section.

14. A navigation device comprising:
at least one processor; and
a memory storing a set of instructions,
wherein the at least one processor executes the set of instructions to perform:
an operation of identifying a type of business related to a destination of a vehicle corresponding to the navigation device;
an operation of determining a charging type based on the type of business;
an operation of identifying at least one charging station including a charger of the charging type among a plurality of charging stations located within a predetermined distance from the destination of the vehicle; and
an operation of providing a user with the at least one charging station as recommended charging stations.

15. The navigation device of claim 14, wherein the operation of determining the charging type includes an operation of determining the charging type as a quick charging type in response to determining that the type of business is a short-term stay business, and
wherein the recommended charging stations include a charger of the quick charging type.

16. The navigation device of claim 14, wherein the operation of determining the charging type includes an operation of determining the charging type as a slow charging type in response to determining that the type of business is a long-term stay business, and
wherein the recommended charging stations include a charger of the slow charging type.

17. The navigation device of claim 14, wherein the operation of determining the charging type includes an operation of determining the charging type based on the type of business and a remaining battery amount of the vehicle.

18. The navigation device of claim 17, wherein the operation of determining the charging type includes an operation of determining the charging type as a quick charging type when the type of business is a short-term stay business and the remaining battery amount of the vehicle is less than a first value, and
wherein the recommended charging stations include a charger of the quick charging type.

19. The navigation device of claim 17, wherein the operation of determining the charging type includes:
an operation of identifying a preferred charging type of the user based on a user charging pattern when the remaining battery amount of the vehicle is more than a second value, and
an operation of determining the charging type as the preferred charging type of the user.

20. A navigation device comprising:
at least one processor; and
a memory storing a set of instructions,
wherein the at least one processor executes the set of instructions to perform:
an operation of acquiring a vehicle charging pattern of a user of a vehicle corresponding to the navigation device;
an operation of acquiring a driving route of the vehicle;
an operation of determining a target sub-section related to a charging station recommendation among a plurality of sub-sections included in the driving route based on the vehicle charging pattern of the user; and
an operation of providing the user with at least one charging station located within a predetermined distance from the target sub-section.
